(19) United States
(12) Patent Application Publication
(10) Pub. No.: US 2012/0318433 A1
(43) Pub. Date: Dec. 20, 2012

(54) METHOD OF MANUFACTURING ORGANIC LIGHT-EMITTING DISPLAY APPARATUS

(76) Inventor: Jae-Ha Lim, Yongin-city (KR)

(21) Appl. No.: 13/424,265

(22) Filed: Mar. 19, 2012

(30) Foreign Application Priority Data
Jun. 14, 2011 (KR) 10-2011-0057606

(51) Int. Cl. B05D 5/12; B32B 38/10

(52) U.S. Cl. 156/67; 427/69

(57) ABSTRACT

A method of manufacturing an organic light-emitting display apparatus includes forming a deposition blocking film on regions of a substrate other than a display region of the substrate, forming a common thin-film layer in the display region by deposition on the substrate on which the deposition blocking film is formed, and removing the deposition blocking film from the substrate after the deposition is complete.

### CROSS-REFERENCE TO RELATED PATENT APPLICATION

This application claims priority to and the benefit of Korean Patent Application No. 10-2011-0057606, filed on Jun. 14, 2011 in the Korean Intellectual Property Office, the disclosure of which is incorporated herein in its entirety by reference.

### BACKGROUND

1. Field

Embodiments of the present invention relate to methods of manufacturing an organic light-emitting display apparatus.

2. Description of the Related Art

Generally, a wide viewing angle, a high contrast ratio, and a rapid response are advantages that organic light-emitting display apparatuses have over other display apparatuses.

An organic light-emitting display apparatus realizes colors on a principle of emitting light by recombining holes and electrons respectively injected from an anode electrode and a cathode electrode into a light-emitting layer. The organic light-emitting display apparatus has a structure in which a light-emitting layer is formed between the anode electrode and the cathode electrode. Also, because a high light emission efficiency might not be obtained by such a structure, generally, intermediate layers, such as a hole injection-transport layer and an electron injection-transport layer, are respectively formed between the anode electrode and the light-emitting layer and the cathode electrode and the light-emitting layer.

Electrodes, thin films including the electrodes, and a light-emitting layer of an organic light-emitting display apparatus are generally formed through deposition processes. In other words, after preparing masks having the same patterns as thin films to be formed and arranging the masks on a substrate, the thin films having desired patterns are formed by depositing a material for forming the thin films.

The types of masks used in the abovementioned deposition processes are fine metal masks (FMMs) for fine patterning, which allow deposition on a predetermined region in a display region, and open masks, which are used for forming a common thin film on an entire display region. For example and with respect to the light-emitting layer, when it is needed to precisely deposit a thin film layer on a defined position in a display region, an FMM is used. With respect to the hole injection-transport layer and the electron injection-transport layer, when it is needed to deposit a common thin-film layer on the entire display region, an open mask with an entire open region is used. Naturally, in the case of the open mask, a high precision pattern at the same level of precision as the FMM is not required.

However, although not requiring a high precision, when the open mask is used, the facilities for transportation, alignment, and washing (after deposition) of the open mask must be provided, and whenever a deposition process is performed, transportation, alignment, and washing using these facilities must be performed. Therefore, there is a large workload in view of the relatively simple use of the open mask. Furthermore, recently, as the size of the organic light-emitting display apparatuses increases, the size of corresponding open masks also increase. Therefore, the transportation of large open masks also requires a large workload.

Therefore, increased workloads may lead to a reduction in productivity.

### SUMMARY

Embodiments of the present invention provide a method of manufacturing an organic light-emitting display apparatus in which common thin-film layers can be deposited without using large open masks that accompany a large workload.

According to an aspect of embodiments of the present invention, there is provided a method of manufacturing an organic light-emitting display apparatus, the method including forming a deposition blocking film on regions of a substrate other than a display region of the substrate, forming a common thin-film layer in the display region by deposition on the substrate on which the deposition blocking film is formed, and removing the deposition blocking film from the substrate after the deposition is complete.

The deposition blocking film may include an adhesive film that is attachable and detachable to and from the regions of the substrate other than the display region.

The forming of the deposition blocking film may include preparing a material film including the adhesive film adhered to a base sheet, moving the material film along an outer circumference of a pressing roller that rotates in tight contact with the substrate, attaching the adhesive film to the substrate by passing the material film between the pressing roller and the substrate, and removing the base sheet from the adhesive film by tightly moving a removing roller having an adhesive force on an outer circumference thereof on the material film that is attached to the substrate.

The forming of the deposition blocking film may include preparing a material film including the adhesive film adhered to a base sheet, attaching edges of the material film to an outer-frame member, a central region of which is exposed, attaching the adhesive film to the substrate by pressing the material film using a pressing roller after placing the outer-frame member on the substrate, and detaching the base sheet from the adhesive film by tightly moving a removing roller having an adhesive force on an outer circumference thereof on the material film that is attached to the substrate.

The removing of the deposition blocking film may include detaching the adhesive film from the substrate by tightly moving a removing roller having an adhesive force on an outer circumference thereof on the adhesive film that is attached to the substrate.

The method may further include aligning attaching points of the adhesive film and the substrate.

The aligning the attaching points may include forming aligning marks respectively on the adhesive film and the substrate, and aligning the attaching points of the adhesive film and the substrate by using a camera to verify the alignment of the aligning marks.

The deposition blocking film may include a coating film.

The forming of the deposition blocking film may include coating a coating material on the substrate, and forming the coating film by drying the coated coating material.

The removing of the deposition blocking film may include detaching the coating film from the substrate by tightly moving a removing roller having an adhesive force on an outer circumference thereof on the coating film formed on the substrate.

The common thin-film layer may include at least one of a hole injection-transport layer for supplying holes to a light-emitting layer included in each pixel in the display region, an electron injection-transport layer for supplying electrons to the light-emitting layer, a facing electrode that faces a pixel electrode with the light-emitting layer interposed therebetween, or a thin film sealing layer that seals the display region.

As described above, according to the method of manufacturing an organic light-emitting display apparatus according to embodiments of the present invention, because a common thin-film layer can be readily deposited without using an open mask, manufacturing processes are thereby simplified, and accordingly, productivity is increased.

### BRIEF DESCRIPTION OF THE DRAWINGS

The above and other features and aspects of embodiments of the present invention will become more apparent by describing in detail exemplary embodiments with reference to the attached drawings in which:

FIG. 1 is a schematic cross-sectional view of an organic light-emitting display apparatus according to an embodiment of the present invention;

FIGS. 2A and 2B are perspective views of a substrate that may be attached to and separated from a deposition blocking film according to an embodiment of the present invention;

FIG. 3 is schematic drawing showing a state of deposition on the substrate of the embodiment shown in FIGS. 2A and 2B, according to an embodiment of the present invention;

FIGS. 4A through 4C are schematic drawings showing a process of forming and removing the deposition blocking film of the embodiment shown in FIGS. 2A and 2B, according to an embodiment of the present invention;

FIGS. 5A through 5C are schematic drawings showing a process of forming and removing the deposition blocking film of the embodiment shown in FIGS. 2A and 2B, according to another embodiment of the present invention; and

FIGS. 6A through 6B are schematic drawings showing a process of forming and removing the deposition blocking film of the embodiment shown in FIGS. 2A and 2B, according to yet another embodiment of the present invention.

### DETAILED DESCRIPTION

Hereafter, embodiments of the present invention will be described more fully with reference to the accompanying drawings, in which exemplary embodiments of the present invention are shown.

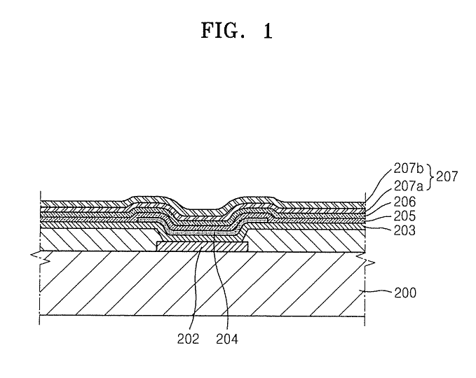

FIG. 1 is a schematic cross-sectional view of an organic light-emitting display apparatus according to an embodiment of the present invention.

The organic light-emitting display apparatus has a structure in which a pixel electrode 202 as an anode electrode, a hole injection-transport layer 203, a light-emitting layer 204, an electron injection-transport layer 205, a facing electrode 206 as a cathode electrode, and a thin film sealing layer 207, are sequentially stacked in the stated order on a substrate 200.

Although not shown, a thin-film transistor (TFT) (not shown) electrically coupled to the pixel electrode 202 is formed on the substrate 200, and when a current flows between the pixel electrode 202 and the facing electrode 206 by a signal from the TFT, light emission occurs in the light-emitting layer 204. The thin film sealing layer 207 is a protective layer that prevents moisture from penetrating into the organic light-emitting display apparatus, and has a structure in which an organic film 207a and an inorganic film 207b are alternately stacked.

Here, the hole injection-transport layer 203, the electron injection-transport layer 205, the facing electrode 206, and the thin film sealing layer 207 are common thin-film layers that are formed on an entire display region 210. Accordingly, the light-emitting layer 204 must be precisely formed in a position corresponding to a pixel.

Therefore, the light-emitting layer 204 is formed by using an FMM that allows a precise patterning. However, because the abovementioned common thin-film layers need to be simply deposited uniformly on the entire display region 210, a precise patterning like that which is used for the light-emitting layer 204 is unnecessary.

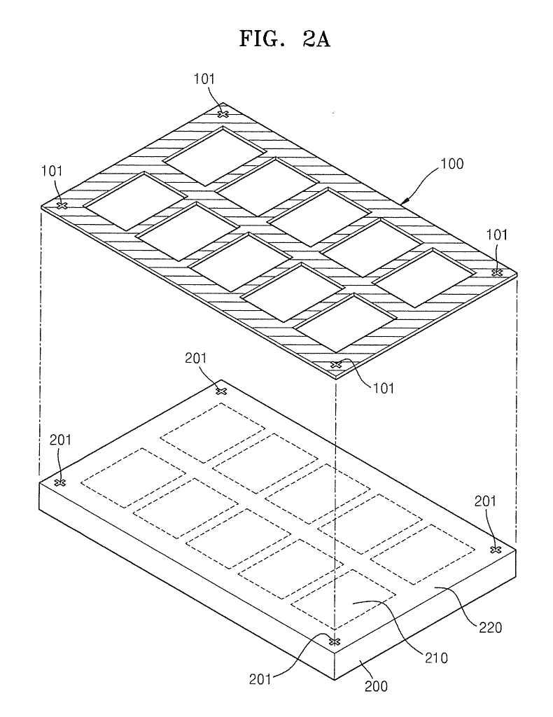

Accordingly, in the present embodiment, to more simply form the common thin-film layers, as depicted in FIGS. 2A and 2B, an adhesive film 100, which is a deposition blocking film, is attached to the substrate 200. In other words, as described above, a metal open mask is conventionally used for forming the common thin-film layers, and the management of the metal open mask requires increased workload.

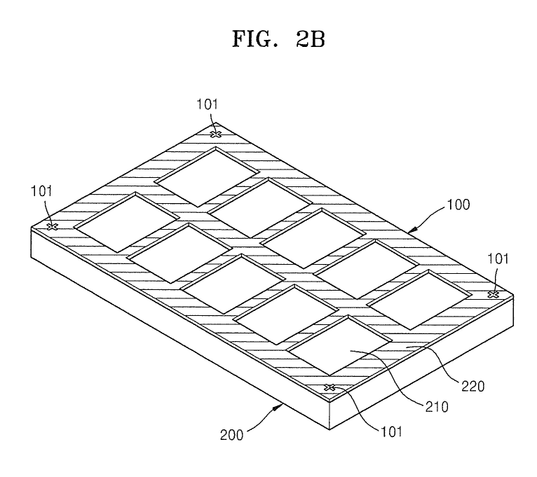

However, in the present embodiment, as depicted in FIGS. 2A and 2B, the adhesive film 100 is attached to the substrate 200 to function as a mask, thereby greatly reducing workload. In other words, instead of using the conventional metal open mask that is difficult to manage because it must be moved, aligned, and washed every time, the adhesive film 100, which is a deposition blocking film, is attached to a remaining region 220, which is separate from the display region 210, on the substrate 200, and, as shown in FIG. 3, deposition of a material from a deposition source 300 is performed, and then the common thin-film layers are easily formed on the entire display region 210. Then, the adhesive film 100 is removed from the substrate 200 after the deposition is complete.

According to embodiments of the present invention, the substrate 200 may be a single unit cell substrate on which only one display region 210 is formed. However, as depicted in FIGS. 2A and 2B, the substrate 200 may be a multi-cell substrate on which a plurality of display regions 210 is formed. In either case, when the display region 210 where a deposition will be performed is exposed, and the remaining region 220 is blocked by attaching the adhesive film 100, the common thin-film layers can be easily formed without using a metal open mask that is difficult to manage.

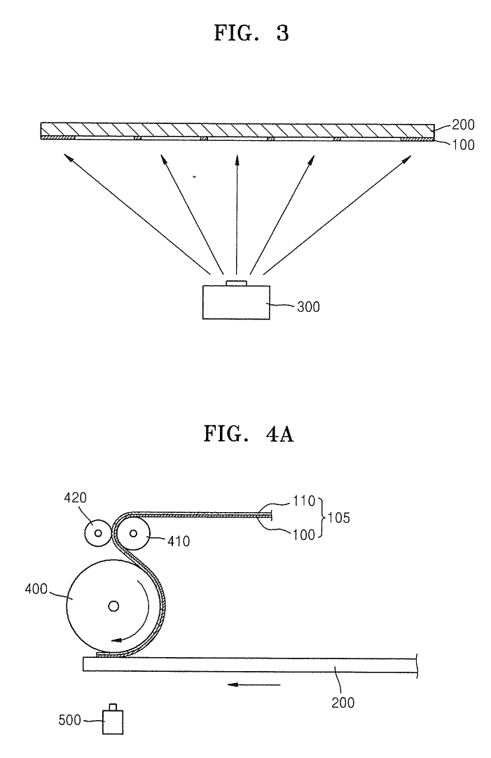

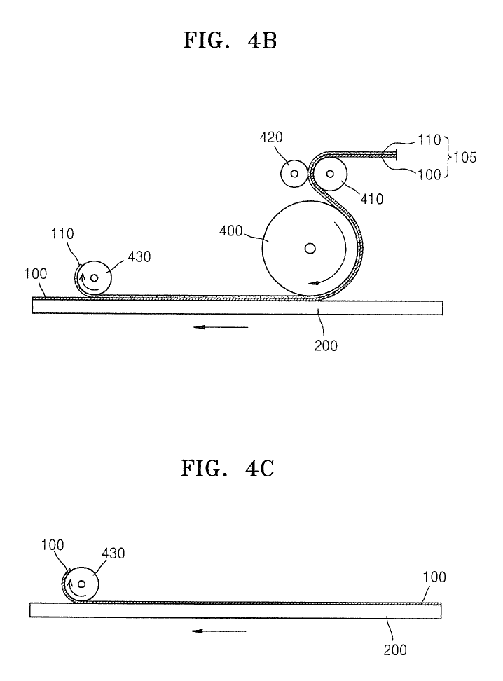

A process of attaching the adhesive film 100 to the substrate 200 is depicted in FIGS. 4A and 4B.

First, the adhesive film 100 is combined with a base sheet 110 to be formed as one body in a type of a material film 105. As shown in FIG. 4A, the material film 105 is moved along an outer circumference of a pressing roller 400 that rotates in tight contact with the substrate 200, and when the material film 105 passes between the substrate 200 and the pressing roller 400, the adhesive film 100 is attached to the substrate 200. The disposition of convey rollers (e.g., conveyor rollers) 410 and 420 is exemplary, and thus, may differ in various ways. For example, like the convey roller 410 depicted in FIG. 4A, if there is a convey roller that contacts the adhesive film 100 of the material film 105 before the substrate 200, adherence of the adhesive film 100 to the corresponding convey roller may be prevented by performing an appropriate coating treatment on the convey roller. Therefore, the convey rollers 410 and 420 can be disposed in various positions according to different embodiments of the present invention.

Before a major attachment operation begins, an aligning operation may be performed using a camera 500. In other words, as depicted in FIG. 4A, first, aligning marks 101 and 201 (see FIG. 2A) respectively formed on the adhesive film 100 and the substrate 200 are checked to determine whether they are sufficiently aligned with each other using the camera 500, and, if necessary, an attachment position of the adhesive film 100 is aligned by controlling the substrate 200. Afterwards, as depicted in FIG. 4B, the major attachment operation is performed.

A removing roller 430 that has an adhesive force on an outer circumference thereof recovers the base sheet 110 on a rear end of the pressing roller 400. In other words, the base sheet 100, which is an upper sheet of the material film 105 that is attached to the substrate 200 via the adhesive film 100, is detached from the adhesive film 100 by an adhesive force and is recovered. Once an end of the base sheet 110 begins to wind on the removing roller 430 by the adhesive force, the base sheet 110 is continuously pulled and detached from the adhesive film 100 due to the winding force of the removing roller 430.

In this way, as depicted in FIG. 2B, the substrate 200, on which only the display region 210 is exposed due to the adhesive film 100, is prepared. When a deposition process is performed in this state, as depicted in FIG. 3, a desired common thin-film layer is formed in the display region 210.

Afterwards, to remove the adhesive film 100, as depicted in FIG. 4C, the removing roller 430 is reused. In other words, when the removing roller 430 having an adhesive force on an outer circumference thereof rolls tightly against the adhesive film 100, the adhesive film 100 is removed from the substrate 200 by attaching to the outer circumference of the removing roller 430. Accordingly, the common thin-film layers may be easily formed through a simple operation of attaching and detaching the adhesive film 100 to and from the substrate 200 instead of using an open mask that is difficult to manage. The common thin-film layers may be the hole injection-transport layer 203, the electron injection-transport layer 205, the facing electrode 206, and/or the thin film sealing layer 207, and the adhesive film 100 may be removed after forming all of the common thin-film layers. Obviously, a precise patterning is performed to form the light-emitting layer 204 using an FMM (not shown) in the course of forming the organic light-emitting display apparatus. However, the light-emitting layer 204 is formed on a pixel position in the display region 210. Therefore, a patterning for forming the light-emitting layer 204 may be formed when the adhesive film 100 is attached to the substrate 200.

Accordingly, as described above, when the method that uses the adhesive film 100 is used according to embodiments of the present invention, the common thin-film layers may be easily deposited without using an open mask that is difficult to manage. Therefore, manufacturing can be simplified to thus increase productivity.

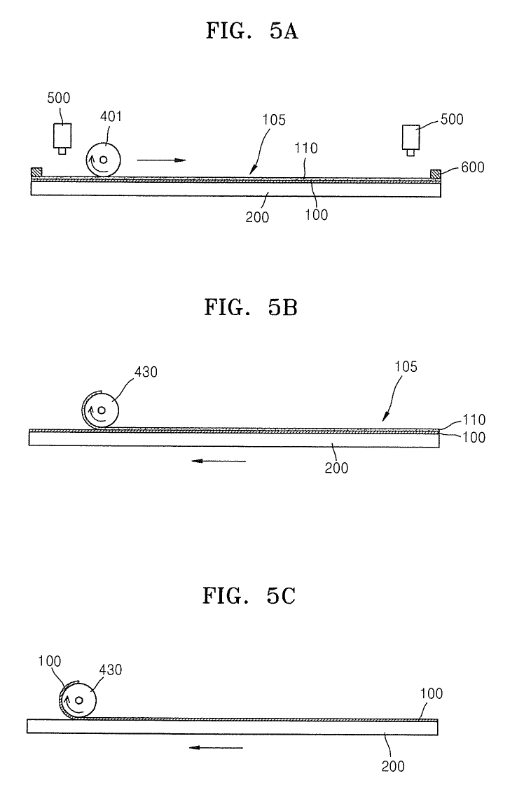

In the above embodiment, the material film 105 moved along an outer circumference of the pressing roller 400 is attached to the substrate 200. However, as shown in FIGS. 5A and 5B, the adhesive film 100 may be attached to the substrate 200 when the adhesive film 100 is fixed on an outer-frame member 600. In other words, edges of the material film 105 are combined with the outer-frame member 600, a central region of which is exposed, and, as depicted in FIG. 5A, the resultant structure is placed on the substrate 200. Afterwards, the material film 105 is attached to the substrate 200 by pressing the material film 105 with a pressing roller 401. As a result, a side of the adhesive film 100 of the material film 105 is adhered to the substrate 200. Before using the pressing roller 401, an aligning operation may be performed using the camera 500. In other words, the aligning marks 101 and 201 (see FIG. 2A) respectively formed on the adhesive film 100 and the substrate 200 are checked to determine whether they are aligned with each other using the camera 500, and, if necessary, an attachment position of the adhesive film 100 is aligned by controlling the substrate 200. Afterwards, the major attachment operation is performed by using the pressing roller 401.

Afterwards, as depicted in FIG. 5B, when the base sheet 110 is detached using the removing roller 430, the substrate 200 on which only the display region 210 is exposed by the adhesive film 100 is prepared, as depicted in FIG. 2B. In this state, as depicted in FIG. 3, when a deposition process is performed, a desired common thin-film layer is formed in the display region 210. After the deposition is complete, as depicted in FIG. 5C, the adhesive film 100 is removed from the substrate 200 by reusing the removing roller 430. Accordingly, a common thin-film layer may be readily formed by using the method according to the present embodiment.

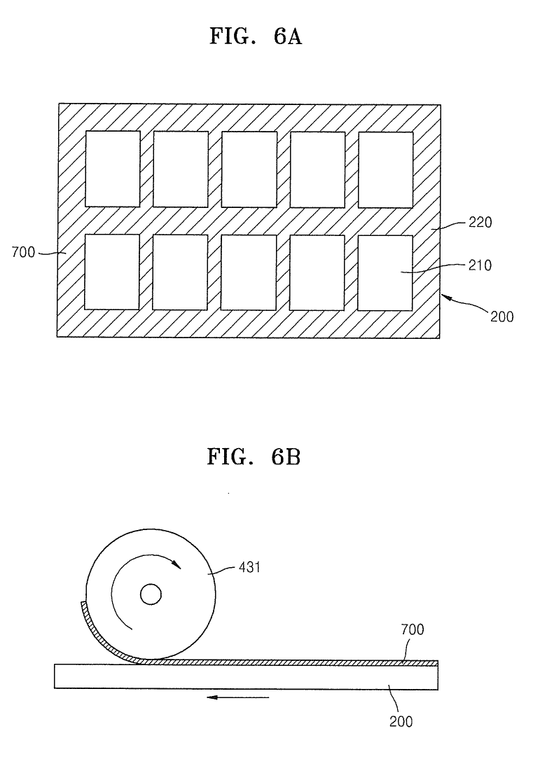

As another embodiment of the present invention, as shown in FIGS. 6A and 6B, a coating film 700 may be used as a deposition blocking film. In other words, the coating film 700 is coated on the substrate 200 on regions excluding the display region 210 (e.g., remaining regions 220) by using a printing method or the coating film 700, and after drying the coating film 700, a deposition blocking film functioning as the adhesive film 100 described above is formed.

When a deposition operation is performed as depicted in FIG. 3 using the coating film 700, a desired common thin-film layer may be formed in the display region 210. After the deposition is complete, as depicted in FIG. 6B, the coating film 700 is removed from the substrate 200 using a removing roller 431 having an adhesive force on an outer circumference thereof. Here, the removing roller 431 of the present embodiment may have a diameter greater than that of the removing roller 430 used in the previous embodiment. This is because, in the previous embodiment, the removing roller 430 detaches the base sheet 110 or the adhesive film 100, which are coupled as one-body and, once an edge of each of the base sheet 110 and the adhesive film 100 is adhered to the removing roller 430, the base sheet 110 and the adhesive film 100 are detached by the winding force of the removing roller 430. However, in the present embodiment, an object to be detached is the coating film 700 formed by a printing method or a dispensing method, and thus, when a winding is performed with adherence of only the edges, the entire coating film 700 may be pulled and may not be detached (e.g., the coating film 700 might not be able to withstand the same degree of tensile force as the adhesive film 100 and the base sheet 110, thereby preventing effective removal from the substrate 200). Accordingly, it is safe to use the removing roller 431 having a length of an outer circumference greater than the length of the coating film 700 to be detached.

Accordingly, a common thin-film layer may be readily formed by using the method according to the present embodiment without using an open mask.

As described above, when methods of manufacturing an organic light-emitting display apparatus according to embodiments of the present invention are used, common thin-film layers may be readily formed without using an open mask that requires increased workload. Accordingly, workability and productivity can be greatly increased.

While embodiments of the present invention have been particularly shown and described with reference to exemplary embodiments thereof, it will be understood by those of ordinary skill in the art that various changes in form and details may be made therein without departing from the spirit and scope of the present invention as defined by the following claims and equivalents thereof.

What is claimed is:

1. A method of manufacturing an organic light-emitting display apparatus, the method comprising:
forming a deposition blocking film on regions of a substrate other than a display region of the substrate;
forming a common thin-film layer in the display region by deposition on the substrate on which the deposition blocking film is formed; and
removing the deposition blocking film from the substrate after the deposition is complete.

2. The method of claim 1, wherein the deposition blocking film comprises an adhesive film that is attachable and detachable to and from the regions of the substrate other than the display region.

3. The method of claim 2, wherein the forming of the deposition blocking film comprises:
preparing a material film comprising the adhesive film adhered to a base sheet;
moving the material film along an outer circumference of a pressing roller that rotates in tight contact with the substrate;
attaching the adhesive film to the substrate by passing the material film between the pressing roller and the substrate; and
removing the base sheet from the adhesive film by tightly moving a removing roller having an adhesive force on an outer circumference thereof on the material film that is attached to the substrate.

4. The method of claim 2, wherein the forming of the deposition blocking film comprises:
preparing a material film comprising the adhesive film adhered to a base sheet;
attaching edges of the material film to an outer-frame member, a central region of which is exposed;
attaching the adhesive film to the substrate by pressing the material film using a pressing roller after placing the outer-frame member on the substrate; and
detaching the base sheet from the adhesive film by tightly moving a removing roller having an adhesive force on an outer circumference thereof on the material film that is attached to the substrate.

5. The method of claim 2, wherein the removing of the deposition blocking film comprises detaching the adhesive film from the substrate by tightly moving a removing roller having an adhesive force on an outer circumference thereof on the adhesive film that is attached to the substrate.

6. The method of claim 2, further comprising aligning attaching points of the adhesive film and the substrate.

7. The method of claim 6, wherein the aligning the attaching points comprises:
forming aligning marks respectively on the adhesive film and the substrate; and
aligning the attaching points of the adhesive film and the substrate by using a camera to verify the alignment of the aligning marks.

8. The method of claim 1, wherein the deposition blocking film comprises a coating film.

9. The method of claim 8, wherein the forming of the deposition blocking film comprises:
coating a coating material on the substrate; and
forming the coating film by drying the coated coating material.

10. The method of claim 8, wherein the removing of the deposition blocking film comprises detaching the coating film from the substrate by tightly moving a removing roller having an adhesive force on an outer circumference thereof on the coating film formed on the substrate.

11. The method of claim 1, wherein the common thin-film layer comprises at least one of a hole injection-transport layer for supplying holes to a light-emitting layer included in each pixel in the display region, an electron injection-transport layer for supplying electrons to the light-emitting layer, a facing electrode that faces a pixel electrode with the light-emitting layer interposed therebetween, or a thin film sealing layer that seals the display region.
